(19) United States
(12) Patent Application Publication
(10) Pub. No.: US 2010/0270992 A1
(43) Pub. Date: Oct. 28, 2010

(54) SEMICONDUCTOR DEVICE

(75) Inventors: Tetsuya KAWASHIMA, Tokai (JP); Takayuki HASHIMOTO, Tokai (JP)

Correspondence Address: BRUNDIDGE & STANGER, P.C., 2318 MILL ROAD, SUITE 1020, ALEXANDRIA, VA, 22314, US

(73) Assignee: RENESAS ELECTRONICS CORPORATION, Kawasaki-shi (JP)

(21) Appl. No.: 12/767,156

(22) Filed: Apr. 26, 2010

(30) Foreign Application Priority Data
Apr. 28, 2009 (JP) 2009-109518

(51) Int. Cl. G05F 1/10; H01L 23/538; H01L 23/52

(52) U.S. Cl. 323/282; 257/692; 257/723; 257/690; 257/E23.174; 257/E23.169; 257/E23.141

(57) ABSTRACT

A semiconductor device having two semiconductor chips sealed in a sealant (2-in-1 package) is provided. A power MOSFET chip for control is disposed on an input-side plate lead portion, wherein a source electrode and a gate electrode are formed on a main surface of the chip and the source electrode is connected to an output plate lead portion. A power MOSFET chip for synchronization is disposed on an output-side plate lead portion, wherein a source electrode and a gate electrode are formed on a main surface of the chip, and the second source electrode is connected to a ground-side plate lead portion. The ground-side plate lead portion and gate-side lead portions connected to the gate electrodes, respectively, are provided between the input-side plate lead portion and the output-side plate lead portion. In this manner, heat-dissipation paths via wirings when the 2-in-1 package is mounted on a board can be wide.

### CROSS-REFERENCE TO RELATED APPLICATION

The present application claims priority from Japanese Patent Application No. 2009-109518 filed on Apr. 28, 2009, the content of which is hereby incorporated by reference into this application.

### TECHNICAL FIELD OF THE INVENTION

The present invention relates to a semiconductor device. More particularly, the present invention relates to a technique effectively applied to a semiconductor device in which a plurality of semiconductor chips are sealed in a sealant.

### BACKGROUND OF THE INVENTION

In a semiconductor device in which two semiconductor chips are sealed in one package and operate as a DC/DC converter, conventionally, the chips are arranged to make a linear path for current to flow. More specifically, a frame having a first chip is mounted thereon, a frame connected to a source electrode of the first chip and having a second chip mounted thereon, and a frame connected to a source electrode of the second chip are arranged in line in this order (e.g., Japanese Patent Application Laid-Open Publication No. 2003-037245 (Patent Document 1)).

### SUMMARY OF THE INVENTION

Insulated DC/DC converters widely used for power sources of CPUs in personal computers are composed of power MOSFETs (metal oxide semiconductor field effect transistors) for control and synchronization, driver ICs (integrated circuits) for turning ON/OFF these MOSFETs, and other components like choke coils and/or capacitors.

Recently, down-sizing of the above-mentioned power sources has been advanced, and development of products in which two power MOSFETs, which compose a DC/DC converter, are sealed in one resin package (2-in-1 package) has been advanced.

As a feature of the 2-in-1 package, in addition to advantages in a reduction of mounting area and a reduction in material cost according to down-sizing, there is a demerit in a degradation of heat-dissipation capacity due to integration.

Degradation of heat-dissipation capacity causes various problems such as a lowering in maximum output current and a lowering in reliability, etc.

A preferred aim of the present invention is to achieve an improvement in heat-dissipation capacity when mounting a 2-in-1 package on a printed circuit board.

The above and other preferred aims and novel characteristics of the present invention will be apparent from the description of the present specification and the accompanying drawings.

The typical ones of the inventions disclosed in the present application will be briefly described as follows.

A semiconductor device according to an embodiment of the present invention is a semiconductor device formed in one package, the semiconductor device comprising: first, second, third, fourth, and fifth terminals; and a first transistor and a second transistor each of which has first, second, and third electrodes, wherein the first and second transistors are sealed in a sealant, the first transistor is mounted on a first conductor member in a plate shape including the first terminal; the second transistor is mounted on a second conductor member in a plate shape including a second terminal; the first electrode of the first transistor is electrically connected to the first terminal; the first electrode of the second transistor is electrically connected to the second terminal; the second electrode of the first transistor is electrically connected to the second terminal; the second electrode of the second transistor is electrically connected to the third terminal; the third electrode of the first transistor is electrically connected to the fourth terminal; the third electrode of the second transistor is electrically connected to the fifth terminal; and the third, fourth and fifth terminals are provided between the first terminal and the second terminal in the package.

The effects obtained by typical aspects of the present invention will be briefly described below.

By arranging two plate-like conductor members on which two semiconductor chips are mounted so that a heat-dissipation path through wirings of a printed circuit board can be wide, an improvement in heat-dissipation capacity of a semiconductor device can be achieved compared with conventional structures.

### BRIEF DESCRIPTIONS OF THE DRAWINGS

FIG. 1 is a plan view illustrating an example of a structure of a semiconductor device viewed through a sealant according to a first embodiment of the present invention;

FIG. 2 is a cross-sectional view illustrating a cross-sectional structure of the semiconductor device cut along the line A-A in FIG. 1;

FIG. 3 is a back view illustrating the structure of the semiconductor device illustrated in FIG. 1;

FIG. 4 is an outline perspective view illustrating the structure of the semiconductor device illustrated in FIG. 1;

FIG. 5 is a plan view illustrating an example of a structure of a semiconductor device viewed through a sealant according to a modification example of the first embodiment of the present invention;

FIG. 6 is a circuit diagram illustrating an example of a circuit when the semiconductor device illustrated in FIG. 1 is mounted;

FIG. 7 is a plan view illustrating an example of a wiring shape when the semiconductor device illustrated in FIG. 1 is mounted;

FIG. 8 is a plan view illustrating an example of a structure of a semiconductor device (single package) viewed through a sealant;

FIG. 9 is a plan view illustrating an example of a wiring shape when the semiconductor device illustrated in FIG. 8 is mounted;

FIG. 10 is a plan view illustrating an example of a structure of a semiconductor device viewed through a sealant;

FIG. 11 is a plan view illustrating an example of a wiring shape when the semiconductor device illustrated in FIG. 10 is mounted;

FIG. 12 is a perspective view illustrating the structure of the semiconductor device illustrated in FIG. 1 viewed through the sealant;

FIG. 13 is a plan view illustrating an example of a structure of a semiconductor device according to a second embodiment of the present invention viewed through a sealant;

FIG. 14 is a cross-sectional view illustrating a cross-sectional structure of the semiconductor device cut along the line B-B in FIG. 13; and

FIG. 15 is a back view illustrating the structure of the semiconductor device illustrated in FIG. 13.

### DESCRIPTIONS OF THE PREFERRED EMBODIMENTS

Hereinafter, in the embodiments of the present invention, repetitive descriptions of the same or similar components will be omitted unless necessary.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Hereinafter, embodiments of the present invention will be described in detail with reference to the accompanying drawings. Also, components having the same function are denoted by the same reference symbols throughout the drawings for describing the embodiments, and the repetitive description thereof is omitted.

### First Embodiment

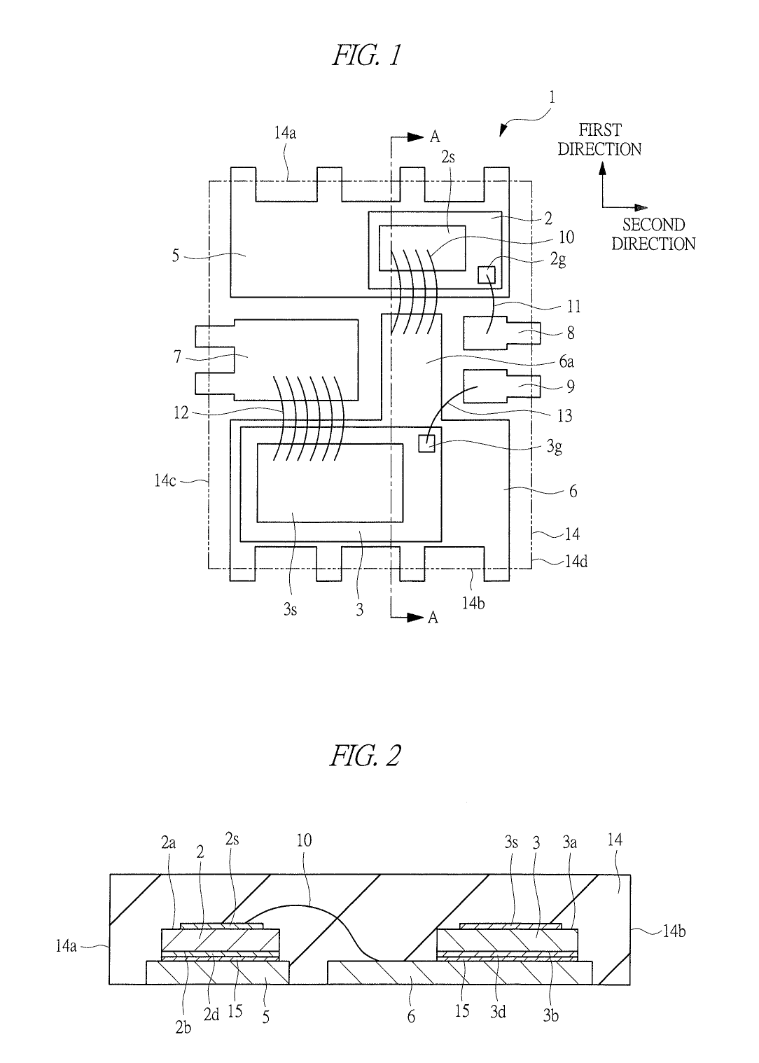

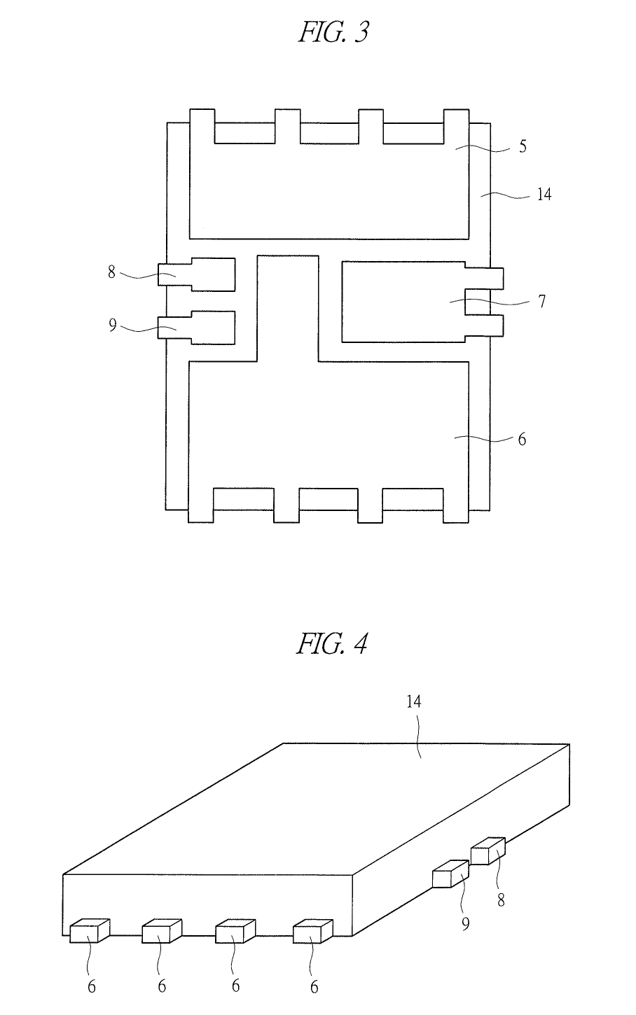

FIG. 1 is a plan view illustrating an example of a structure of a semiconductor device (2-in-1 package of a non-insulated DC/DC converter) viewed through a sealant 14 according to a first embodiment of the present invention. FIG. 2 is a cross-sectional view illustrating a cross-sectional structure of the 2-in-1 package 1 cut along the line A-A in FIG. 1. FIG. 3 is a back view illustrating the structure of the semiconductor device illustrated in FIG. 1. FIG. 4 is an outline perspective view illustrating the structure of the semiconductor device illustrated in FIG. 1. Also, FIG. 12 is a perspective view illustrating the semiconductor device illustrated in FIG. 1 viewed through the sealant 14. Note that, in FIG. 1, the outline of the sealant 14 is illustrated by a dashed-two dotted line so that an internal structure of the 2-in-1 package 1 is easy to understand.

The semiconductor device according to the present embodiment illustrated in FIGS. 1 to 4 and FIG. 12 includes two semiconductor chips sealed in one sealant (insulating resin for sealing) 14. In the present embodiment, as an example of the semiconductor device, the 2-in-1 package 1 for a non-insulating DC/DC converter will be exemplified and described.

Note that, as illustrated in FIGS. 3 and 4, the 2-in-1 package has a structure in which a plurality of terminals are arranged on a back surface or outer edge of the sealant 14.

A basic structure of the 2-in-1 package 1 of the present embodiment includes: two semiconductor chips having transistor circuits; two plate-like conductor members on which the two semiconductor chips are mounted; a plurality of plate-like conductor members electrically connected to an electrode of at least one of the semiconductor chips; and the sealant 14 which seals the two semiconductor chips, wherein a part of the plate-like conductor members is exposed from the sealant 14 to form terminals.

Note that the 2-in-1 package includes a power MOSFET chip for control 2 that is a first semiconductor chip, and a power MOSFET chip for synchronization 3 that is a second semiconductor chip electrically connected to the power MOSFET chip for control 2 by a conductor member, wherein these two semiconductor chips are sealed (encapsulated) in the sealant 14.

To describe the structure of the 2-in-1 package of the present embodiment in more detail, as illustrated in FIGS. 1 and 2, the power MOSFET chip for control (first transistor) 2 is disposed on an input-side plate lead portion (first plate-like conductor member) 5. More specifically, on a back surface 2b of the power MOSFET chip for control 2, a terminal portion that will be a drain electrode (first electrode) 2d of the power MOSFET for control 2 is formed, and the input-side plate lead portion 5 that is a first plate-like conductor member is electrically connected to the drain electrode 2d by a die-bonding material, for example, solder 15.

On a main surface 2a of the power MOSFET chip for control 2, terminal portions to be a source electrode (second electrode) 2s and a gate electrode (third electrode) 2g of the power MOSFET for control 2 are formed.

Further, the power MOSFET chip for synchronization (second transistor) 3 is disposed on an output-side plate lead portion (second plate-like conductor member) 6. More specifically, on a back surface 3b of the power MOSFET chip for synchronization 3, a terminal portion to be a drain electrode (first electrode) 3d of the power MOSFET chip for synchronization 3 is formed, and an output-side plate lead portion 6 that is a second plate-like conductor member is electrically connected to the drain electrode 3d by a die-bonding material, for example, solder 15.

On a main surface 3a of the power MOSFET chip for synchronization 3, terminal portions to be a source electrode (second electrode) 3s and a gate electrode (third electrode) 3g of the power MOSFET for synchronization 3 are formed.

The 2-in-1 package 1 includes a ground-side plate lead portion 7 and gate-side lead portions 8 and 9. The source electrode 2s on the main surface 2a of the power MOSFET chip for control 2 is electrically connected to the output-side plate lead portion 6 via a wire 10 that is a conductor. The source electrode 3s on the main surface 3a of the power MOSFET chip for synchronization 3 is electrically connected to the ground-side plate lead portion 7 via a wire 12 that is a conductor. Further, the gate electrode 2g of the power MOSFET chip for control 2 is electrically connected to the gate-side lead portion 8 via a wire 11 that is a conductor, and the gate electrode 3g of the power MOSFET chip for synchronization 3 is electrically connected to the gate-side lead portion 9 via a wire 13 that is a conductor.

Here, as illustrated in FIG. 1, the ground-side plate lead portion 7 and the gate-side lead portions 8 and 9 are configured to be sandwiched between the input-side plate lead portion 5 and the output-side plate lead portion 6.

More specifically, in the back-surface terminal shape in FIG. 3, there are no other lead portions (terminals) provided on the top, left, and right of the input-side plate lead portion 5, and there are no other lead portions (terminals) provided on the bottom, left, and right of the output-side plate lead portion 6.

As illustrated in FIG. 1, the sealant 14 forming the 2-in-1 package 1 has a rectangular outline in its plane, and has sidewalls at four sides including two sides along a first direction and two sides along a second direction that is perpendicular to the first direction in the plane of the 2-in-1 package 1. That is, the outline in the plane of the sealant 14 is configured by sidewalls 14a and 14b arranged in parallel to each other along the second direction, and sidewalls 14c and 14d arranged along the first direction and contacting the sidewalls 14a and 14b at edge portions in the second direction of the sidewalls 14a and 14b, respectively.

As illustrated in FIG. 1, in the 2-in-1 package 1, the input-side plate lead portion 5 and the output-side plate lead portion 6 are formed in line in the first direction in the plane of the 2-in-1 package 1. In the first direction, no other lead portions (terminals) are formed in the direction from the input-side lead portion 5 to the sidewall 14a in the 2-in-1 package 1. In addition, no other lead portions (terminals) are formed at side portions of the input-side plate lead portion 5 under the power MOSFET chip for control 2.

Similarly, in the 2-in-1 package 1, no other lead portions (terminals) are formed in a direction from the output-side plate lead portion 6 to the sidewall 14b. Also, no other lead portions (terminals) are formed at side portions of the output-side plate lead portion 6 under the power MOSFET chip for synchronization 3 in the second direction. Note that the output-side lead portion 6 under the power MOSFET chip for synchronization 3 mentioned above does not include an extension portion 6a that is a part of the output-side plate lead portion 6 not having the power MOSFET chip for synchronization 3 formed thereabove.

In other words, the input-side plate lead portion 5 is formed in a vicinity of the sidewall 14a at a side along the second direction of the four sidewalls of the sealant 14, and the output-side plate lead portion 6 is formed in a vicinity of the sidewall 14b at a side opposite to the sidewall 14a where the input-side plate lead portion 5 is formed nearby. No other lead portions (terminals) are formed between the input-side plate lead portion 5 and the sidewall 14a where the input-side plate lead portion 5 is formed nearby, and similarly, no other lead portions (terminals) are formed between the output-side lead plate portion 6 and the sidewall 14b where the output-side plate lead portion 6 is formed nearby.

In addition, in the second direction, both ends of the input-side plate lead portion 5 and the output-side plate lead portion 6 are perpendicularly in contact with the sidewalls 14a and 14b of the four sidewalls of the sealant 14, respectively, and positioned in vicinities of the sidewalls 14c and 14d along the first direction, respectively. That is, one end of the input-side plate lead portion 5 in the second direction is arranged in a vicinity of the sidewall 14c, and the other end of input-side plate lead portion 5 in the second direction is arranged in a vicinity of the sidewall 14d. Similarly, one end of the output-side plate lead portion 6 in the second direction is arranged in a vicinity of the sidewall 14c, and the other end of output-side plate lead portion 6 in the second direction is arranged in a vicinity of the sidewall 14d. No other lead portions (terminals) are formed between the sidewall 14c and the end in the second direction of the input-side plate lead portion 5, and no other lead portions (terminals) are formed between the sidewall 14c and the end in the second direction of the output-side plate lead portion 6. Similarly, no other lead portions (terminals) are formed between the sidewall 14d and the end in the second direction of the input-side plate lead portion 5, and no other lead portions (terminals) are formed between the sidewall 14d and the end in the second direction of the output-side plate lead portion 6.

Herein, the back surfaces of the input-side plate lead portion 5, output-side plate lead portion 6, ground-side plate lead portion 7, gate-side lead portion 8, and gate-side lead portion 9 are exposed from the sealant 14 for the purpose of improving heat-dissipation capacity when the 2-in-1 package 1 is mounted on the printed circuit board.

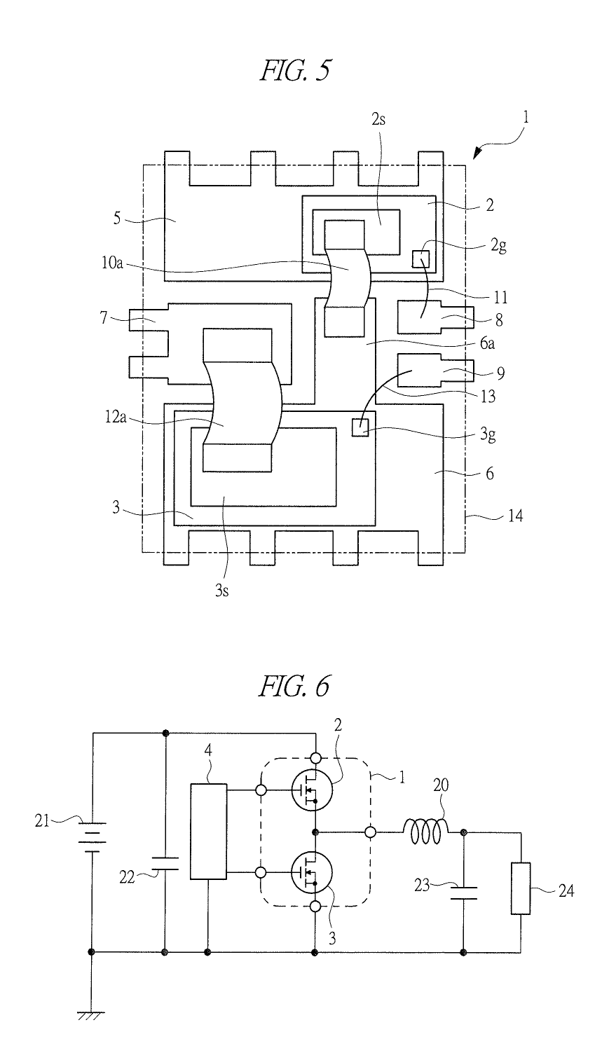

Note that, as illustrated in the modification example in FIG. 5, conductors 10a and 12a of ribbon-shaped conductors can be used for the connection between the source electrode of the MOSFET and the frame. Also, similarly, a plate-shaped conductor can be used. Note that, in FIG. 5, to facilitate understanding of the internal structure of the 2-in-1 package 1, the outline of the sealant 14 is illustrated by a dashed-two dotted line.

Next, FIG. 6 illustrates an example of a circuit when the 2-in-1 package 1 is mounted. The 2-in-1 package 1 is connected via wirings etc. to a driver IC 4, a coil 20, capacitors 22 and 23, and moreover, a resistor 24, an input power source 21 etc. to configure a non-insulated DC/DC converter circuit. In the present circuit, most of heat generated therefrom is from the power MOSFET chip for control 2 and the power MOSFET chip for synchronization 3.

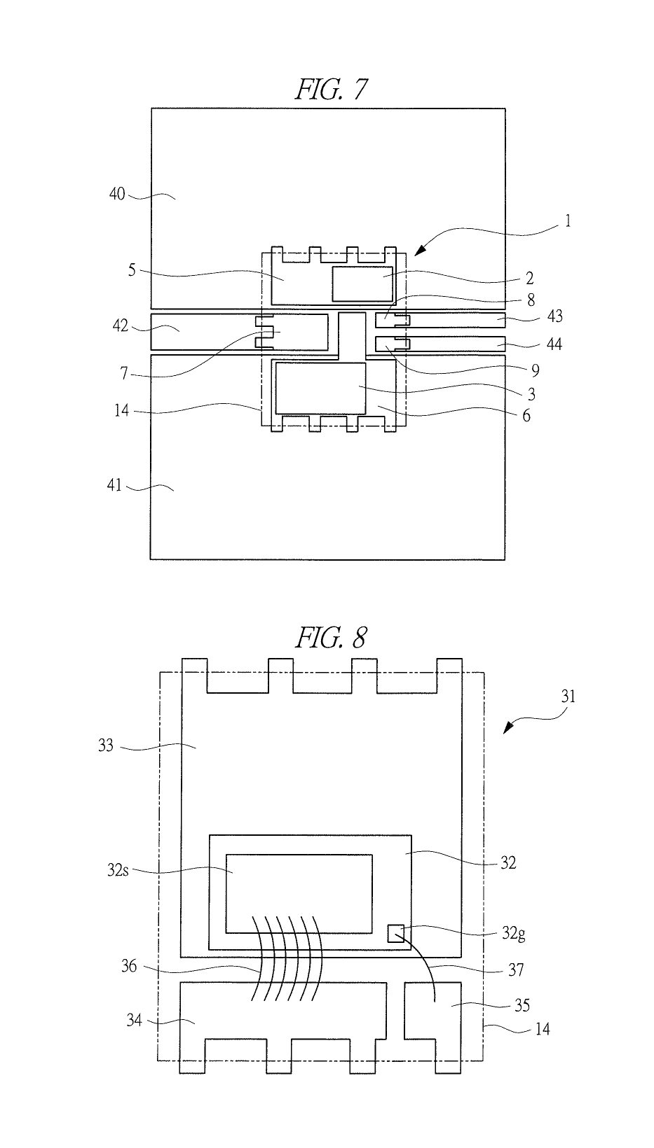

FIG. 7 illustrates an example of a wiring shape in the case of mounting the 2-in-1 package 1 on a printed circuit board. The input-side plate lead portion 5 and an input-side wiring 40; the output-side plate lead portion 6 and an output-side wiring 41; the ground-side plate lead portion 7 and a ground-side wiring 42; and the gate-side lead portions 8 and 9 and gate wirings 43 and 44 are connected using solder or the like, respectively. Note that the printed circuit board on which each of the wirings is formed is not illustrated.

Here, the heat generated from the power MOSFET chip for control 2 and the power MOSFET chip for synchronization 3 is dissipated mainly through the wirings on the printed circuit board. In FIG. 7, the heat generated from power MOSFET chip for control 2 has main heat-dissipation paths in the upward direction and the horizontal direction, and the heat from power MOSFET chip for synchronization 3 has main heat-dissipation paths in the downward direction and the horizontal direction. Note that, in FIG. 7, to facilitate understanding of the internal structure of the 2-in-1 package 1, the outline of the sealant 14 is illustrated by a dashed-two dotted line.

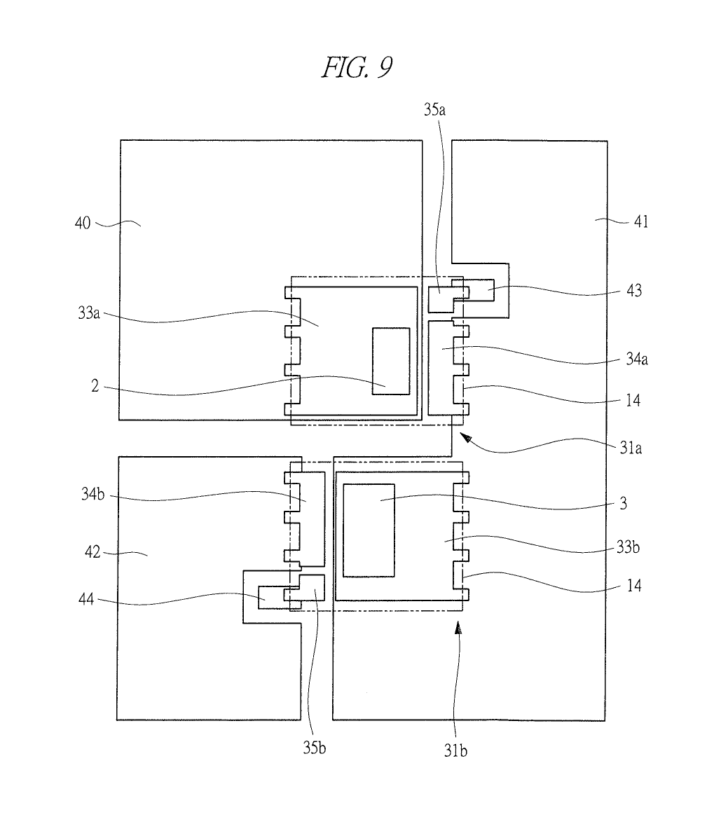

Here, a state of mounting according to a conventional structure is described for comparison. FIG. 8 is a plan view illustrating an example of an individual package sealed in the sealant 14 viewed through the sealant 14, and FIG. 9 is a plan view illustrating an example of a wiring shape in the case of mounting two individual packages 31a and 31b configuring a DC/DC converter on a printed circuit board. Note that, in FIGS. 8 and 9, to facilitate understanding of the internal structures of the individual packages 31, 31a, and 31b, the outline of the sealant 14 is illustrated by a dashed-two dotted line.

To describe a structure of the individual package 31 in detail, as illustrated in FIG. 8, a power MOSFET chip 32 is disposed on a drain-side plate lead portion 33. More specifically, on a back surface of the power MOSFET chip 32, a terminal portion to be a drain electrode (first electrode) of the power MOSFET is formed, and the drain-side plate lead portion 33 is electrically connected to the drain electrode by a die-bonding material, for example, solder.

On a main surface of the power MOSFET chip 32, terminal portions to be a source electrode (second electrode) 32s and a gate electrode (third electrode) 32g of the power MOSFET are formed, and they are electrically connected to a source-side lead portion 34 and a gate-side lead portion 35, respectively, using conductors such as wires 36 and 37.

When mounting the individual packages 31a and 31b on the printed circuit board, as illustrated in FIG. 9, the drain-side plate lead portion 33a of the individual package 31a including the power MOSFET chip for control 2 and the input-side wiring 40; a source-side lead portion 34a and the output-side wiring 41; a gate-side lead portion 35a and the gate wiring 43 for the power MOSFET chip for control are connected using solder or the like, respectively. Further, the drain-side plate lead portion 33b of the individual package 31b including the power MOSFET chip for synchronization 3 and the output-side wiring 41; a source-side lead portion 34b and the ground-side wiring 42; and a gate-side lead portion 35b and the gate wiring 44 for the power MOSFET for synchronization are connected using solder or the like, respectively. Note that, the printed circuit board on which each of the wirings is formed is not illustrated.

Here, in FIG. 9, the heat generated from the power MOSFET chip for control 2 has heat-dissipation paths in the upward direction and leftward direction, and the heat generated from the power MOSFET chip for synchronization 3 has heat-dissipation paths in the downward direction and rightward direction. In this case, the heat-dissipation paths are narrower than those of the 2-in-1 package illustrated in FIG. 7, and thus there is a problem of worse heat-dissipation capacity of the heat generated from the power MOSFET chip for control 2 and power MOSFET chip for synchronization 3.

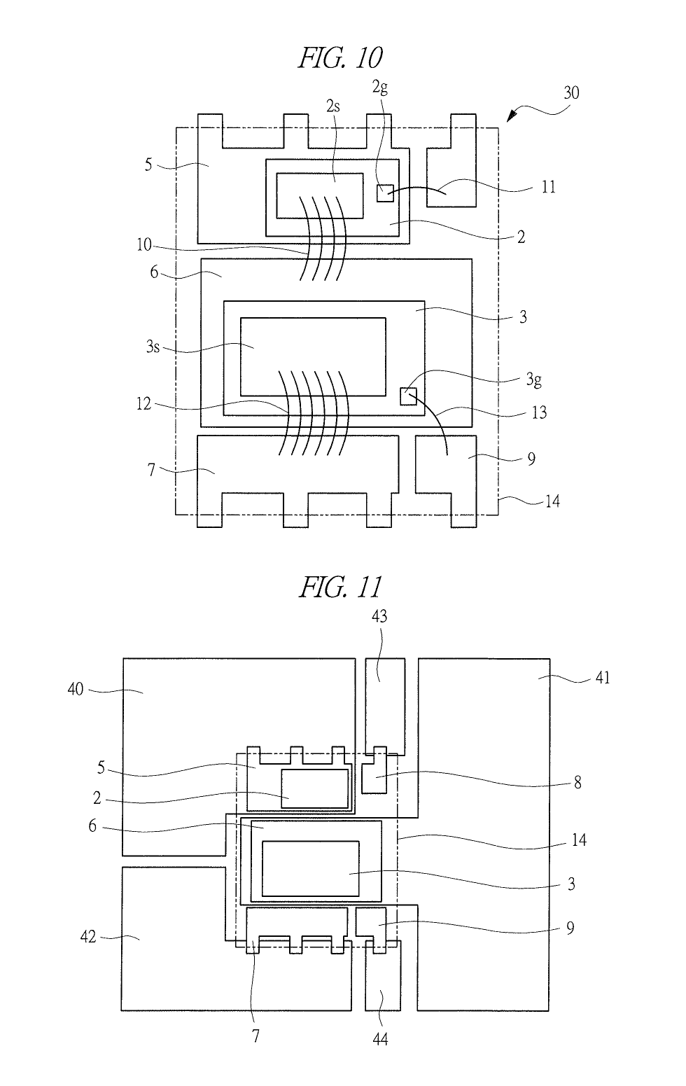

Next, FIG. 10 is a plan view illustrating an example of a 2-in-1 package 30 of a conventional structure viewed through a sealant. The electrical connection relationship between the power MOSFET chips 2 and 3 and each lead portion is the same with that of the 2-in-1 package 1 of the present embodiment, but the positional relation among respective leads is different, wherein the input-side lead portion 5, output-side lead portion 6, and ground-side lead portion 7 are provided in line in this order. Note that, in FIG. 10, to facilitate understanding of the internal structure of the 2-in-1 package 1, the outline of the sealant 14 is illustrated by a dashed-two dotted line.

When mounting the 2-in-1 package 30 having a conventional structure on a printed circuit board, shapes of the input-side wiring 40 and the output-side wiring 41 which are main heat-dissipation paths are as illustrated in FIG. 11. Note that, in FIG. 11, to facilitate understanding of the internal structure of the 2-in-1 package 30, an outline of the sealant 14 is illustrated by a dashed two-dotted line.

Here, in FIG. 11, the heat generated from the power MOSFET chip for control 2 has main heat-dissipation paths in the upward direction and the leftward direction of FIG. 11, and the heat generated from the power MOSFET chip for synchronization 3 has a main heat-dissipation path only in the rightward direction of FIG. 11. These heat-dissipation paths in FIG. 11 are narrower than those of the 2-in-1 package 1 of the first embodiment illustrated in FIG. 7, and thus have a problem of worse heat-dissipation capacity of the heat generated from the power MOSFET chip for control 2 and power MOSFET chip for synchronization 3 similar to the example of FIG. 9. Note that the printed circuit board on which respective wirings are formed is not illustrated.

Also, in FIGS. 1 and 5, the source electrode 2s of the power MOSFET chip for control 2 is connected to the extension portion 6a of the output-side plate lead portion 6 via the wire 10, the ribbon-like conductor 10a, or the like. This way achieves ensuring an easiness in manufacture and reducing loss due to conducting current by means of shortening the length of the wire 10 or the ribbon-like conductor 10a etc., and also achieves separately arranging the heat sources of the two power MOSFET chips 2 and 3.

From the consideration of the above-mentioned points, according to the 2-in-1 package 1 of the present embodiment, the semiconductor chips are arranged at two opposing edges inside the package so that the two semiconductor chips which are heat sources are separately arranged, thereby enabling mounting of the package on a printed circuit board having wider heat-dissipation paths. Thus, the heat-dissipation capacity when the package is mounted on a circuit board can be improved.

### Second Embodiment

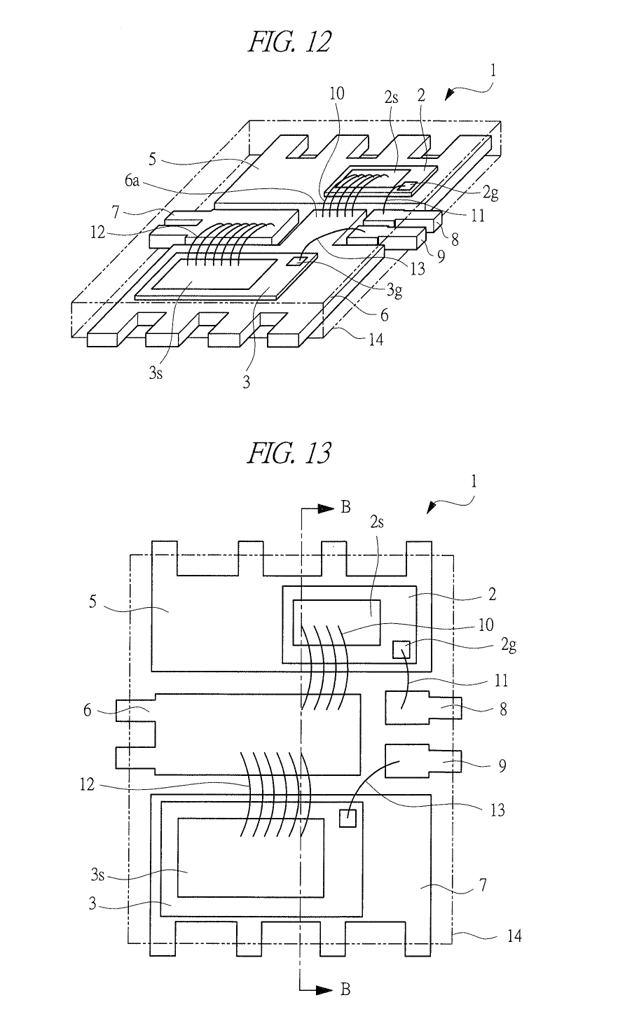

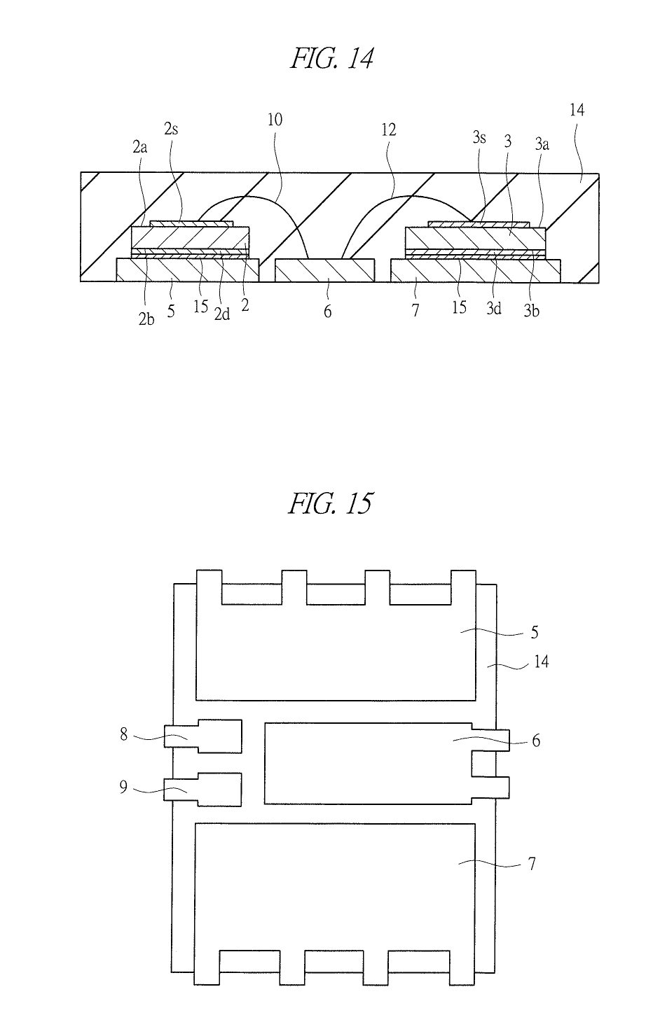

FIG. 13 is a plan view illustrating an example of a structure of a semiconductor device (2-in-1 package for non-insulated DC/DC converter) viewed through a sealant according to a second embodiment of the present invention. FIG. 14 is a cross-sectional view illustrating a cross-sectional structure of the semiconductor device cut along the line B-B in FIG. 13. FIG. 15 is a back view illustrating the structure of the semiconductor device illustrated in FIG. 13. Note that, in FIG. 13, to facilitate understanding of the internal structure of a 2-in-1 package 1, an outline of a sealant 14 is illustrated by a dashed two-dotted line.

In the semiconductor device of the present embodiment illustrated in FIGS. 13 to 15, similarly to the first embodiment, two semiconductor chips are sealed in one sealant (insulating resin for sealing) 14. The 2-in-1 package 1 for a non-insulated DC/DC converter will be exemplified and described as an example of the semiconductor device.

A basic structure of the 2-in-1 package 1 of the present embodiment includes, similarly to that of the first embodiment: two semiconductor chips having transistor circuits; two plate conductor members to mount the two semiconductor chips thereon; a plurality of plate conductor members electrically connected to an electrode of at least one of the semiconductor chips; and the sealant 14 to seal the two semiconductor chips, wherein part of the plate conductor member is exposed from the sealant 14 to form terminals.

Meanwhile, differently from the first embodiment, the power MOSFET chip for synchronization (second transistor) 3 is disposed on a second plate conductor member that is the ground-side plate lead portion 7. More specifically, on the back surface 3b of the power MOSFET chip for synchronization 3, a terminal portion to be the drain electrode (first electrode) 3d of the power MOSFET chip for synchronization 3 is formed, and the ground-side plate lead portion 7 that is a second plate conductor member is electrically connected to the drain electrode 3d via a die-bonding material, for example, solder 15.

Also, on the main surface 3a of the power MOSFET chip for synchronization 3, the source electrode (second electrode) 3s of the power MOSFET chip for synchronization 3 is formed and electrically connected to the output-side plate lead portion 6 via the wire 12 of a conductor.

Here, as illustrated in FIG. 13, the output-side plate lead portion 6 and the gate-side lead portions 8 and 9 are formed to be sandwiched between the input-side plate lead portion 5 and the ground-side plate lead portion 7.

Such a structure can be achieved by using an n-channel MOSFET for the power MOSFET chip for control (first transistor) 2 and a p-channel MOSFET for the power MOSFET chip for synchronization (second transistor) 3.

Since the extension portion 6a of a plate lead is not provided in the 2-in-1 package 1 of the present embodiment as compared with the first embodiment, the structure of leads can be simplified, and the space for the bonding position for the leads to the wires 10 and 12 can be wider, thereby easing the processing.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention is suitable for semiconductor devices and electronics devices.

What is claimed is:

1. A semiconductor device formed in one package, the semiconductor device comprising:
first, second, third, fourth, and fifth terminals; and
a first transistor and a second transistor each of which has first, second, and third electrodes, wherein
the first and second transistors are sealed in a sealant,
the first transistor is mounted on a first conductor member in a plate shape including the first terminal,
the second transistor is mounted on a second conductor member in a plate shape including a second terminal,
the first electrode of the first transistor is electrically connected to the first terminal,
the first electrode of the second transistor is electrically connected to the second terminal,
the second electrode of the first transistor is electrically connected to the second terminal,
the second electrode of the second transistor is electrically connected to the third terminal,
the third electrode of the first transistor is electrically connected to the fourth terminal,
the third electrode of the second transistor is electrically connected to the fifth terminal, and
the third, fourth and fifth terminals are provided between the first terminal and the second terminal in the package.

2. The semiconductor device according to claim 1, wherein
the second and third electrodes of the first transistor are formed on a main surface of the first transistor, and the first electrode of the first transistor is formed on a back surface of the first transistor; and
the second and third electrodes of the second transistor are formed on a main surface of the second transistor, and the first electrode of the second transistor is formed on a back surface of the second transistor.

3. The semiconductor device according to claim 1, wherein
the second conductor member has an extension portion that is a part of the second conductor member extending toward a vicinity of the first conductor member.

4. The semiconductor device according to claim 1, wherein
the second electrode of the first transistor is electrically connected to the second terminal at the extension portion of the second conductor member.

5. The semiconductor device according to claim 1, wherein
the semiconductor device is mounted on a printed circuit board,
the first conductor member is connected to a first wiring pattern of the printed circuit board,
the second conductor member is connected to a second wiring pattern of the printed circuit board, and
the third, fourth, and fifth terminals are connected to third, fourth, and fifth wiring patterns of the printed circuit board provided between the first wiring pattern and the second wiring pattern, respectively.

6. The semiconductor device according to claim 1, wherein
a DC/DC converter is configured by the first transistor and the second transistor.

7. The semiconductor device according to claim 1, wherein
a back surface of the first conductor member and a back surface of the second conductor member are exposed from the package.

8. The semiconductor device according to claim 1, wherein
all of terminals provided on a first side surface of the package are part of the first conductor member, and
all of terminals provided on a second side surface of the package are part of the second conductor member.

9. The semiconductor device according to claim 1, wherein
the package has, between its top surface and bottom surface:
a first sidewall along a first direction;
a second sidewall parallel to the first sidewall; and
third and fourth sidewalls in contact with the first and second sidewalls at both ends of the first and second sidewalls, respectively, and crossing a second direction orthogonal to the first direction and along a plane of the package, wherein
no other terminals are formed between the first conductor portion and the first sidewall,
no other terminals are formed between the second conductor portion and the second sidewall,
no other terminals are formed between both ends in the first direction of the first conductor portion and the third and fourth sidewalls, respectively, and
no other terminals are formed between both ends in the first direction of the second conductor portion and the third and fourth sidewalls, respectively.

10. The semiconductor device according to claim 1, wherein
the second electrode of the first transistor is electrically connected to the second conductor member via a metal wire.

11. The semiconductor device according to claim 1, wherein
the second electrode of the first transistor is electrically connected to the second conductor member via a metal ribbon.

12. The semiconductor device according to claim 1, wherein
the second electrode of the second transistor is electrically connected to the third terminal via a metal wire.

13. The semiconductor device according to claim 1, wherein
the second electrode of the first transistor is electrically connected to the third terminal via a metal ribbon.
